(19) United States
(12) Patent Application Publication
(10) Pub. No.: US 2026/0036607 A1
(43) Pub. Date: Feb. 5, 2026

(54) TEST CONTACT, TABLE DEVICE, TEST CONTACT HOLDING DEVICE, AND METHOD FOR RECEIVING A TEST CONTACT IN A SIMPLIFIED MANNER WITH AN ACTIVE PRE-ALIGNMENT PROCESS USING ELECTROMAGNETIC MANIPULATION

(71) Applicant: PAC TECH - PACKAGING TECHNOLOGY GMBH, Nauen (DE)

(72) Inventors: Thorsten Krause, Hoppegarten (DE); Andreas Meinecke, Berlin (DE); Christopher Schulz, Ketzin/Havel (DE); Lars Titerle, Nauen (DE)

(21) Appl. No.: 18/992,551

(22) PCT Filed: Jul. 25, 2023
(86) PCT No.: PCT/EP2023/070560

§ 371 Date: Jan. 8, 2025

(30) Foreign Application Priority Data
Apr. 26, 2023 (DE) 10 2023 110 670.8

(51) Int. Cl. G01R 1/073

(52) U.S. Cl. CPC G01R 1/07392

(57) ABSTRACT

The invention relates to a test contact (10) comprising a contact tip (11) and a contact body (12), the test contact (10) having an erecting direction (13) and the test contact (10) comprising a core (14) made of a ferromagnetic material, the core being disposed below a center of gravity (15) of the test contact (10) in the erecting direction (13). Furthermore, the invention relates to a table device (20) for handling a test contact (10) and to a method for handling a test contact (10) by means of the table device (20). The invention also relates to a test contact holding device comprising a test contact holder (40) for handling a test contact (10) and to a method for handling a test contact (10) by means of the test contact holding device comprising the test contact holder (40).

The invention relates to a test contact comprising a contact tip and a contact body, to a table device for handling a test contact comprising a contact tip and a contact body, to a method for handling a test contact comprising a contact tip and a contact body by means of a table device for handling a test contact, to a test contact holding device for handling a test contact comprising a contact tip and a contact body and to a method for handling a test contact comprising a contact tip and a contact body by means of a test contact holding device for handling a test contact.

From the state of the art, test contacts are known which connect two or more electronic components, in particular for conducting electrical energy, to each other. In general, the test contacts are permanently connected to a first component and the second component is mounted on a contact tip of the test contact partly protruding from the first component. In addition to the conductive connection, the test contacts can additionally or alternatively serve to mechanically stabilize two or more components with each other. To ensure the stabilization of the mechanical connection and/or to produce two or more conductive connections to form a more complex circuit, it is also common to use two or more test contacts to connect two components. To dispose the test contact correctly on the first component, it is necessary to dispose it so as to be correctly aligned on or in the first component. In this case, the underside or another part of the test contact is disposed on or in the first component, while the contact tip faces away from the first component. Therefore, the handling of the test contact is easiest in terms of the process if the contact tip can be gripped approximately from above, in other words from the direction in which the contact tip points.

The problem here is that because of the design, the test contact comes to rest on the side under the influence of gravity. Particularly in the case of very small structures, for example in microtechnology, it is not possible to grip the test contact reliably at the contact tip or it involves considerable effort. Generally, changing the grip several times by means of two or more tools or manual corrections is necessary for correct gripping. However, this means that additional time in addition to the complex use of several tools is required. The tools must be carefully matched to each other in terms of the process in order to guarantee damage-free handling.

Thus, there is a high demand for a test contact, a table device for handling the test contact and a method for handling the test contact by means of the table device, which overcome the problems known from the state of the art and ensure a quick, safe and reliably correct gripping of the test contact for further handling, in particular for being installed in an electronic component.

The test contact, the table device and the method are intended to facilitate and accelerate in particular the gripping of the test contact and to minimize the use of tools and labor force. In particular, the correct gripping of the test contact is to be ensured.

This object is attained in a surprisingly simple but effective manner by a test contact according to claim 1, a table device for handling a test contact according to claim 6 and a method for handling a test contact by means of the table device according to claim 13.

The invention proposes a test contact comprising a contact tip and a contact body, the contact body having an erecting direction. The test contact is characterized in that the test contact comprises a core made of a ferromagnetic material, the core being disposed below a center of gravity of the test contact in the erecting direction.

The invention is based on the idea that a test contact resting on its side erects itself at least partially in a magnetic field due to the core of ferromagnetic material being disposed below the center of gravity, so that the contact tip lifts off the ground and can be gripped safely and reliably by a tool. The erecting occurs because the magnetic force pulls the core more strongly than the surrounding material of the test contact. Erecting is understood to mean that the test contact rests with one or more surfaces on the ground and is twisted under the influence of the magnetic pull of the magnetic field in such a way that the underside of said test contact rests on the ground. Depending on the initial position and design of the test contact, the erecting can also involve tilting the test contact over one or more edge(s). In other words, the test contact works in the same way as a roly-poly toy, but not due to the pull of gravity, but due to the pull of a magnetic field. The ferromagnetic core shifts a “magnetic center of gravity” of the test contact downwards, just as a heavier material in a roly-poly toy shifts the center of gravity downwards. The lifting of the contact tip creates a distance between the contact tip and the ground, and enables the contact tip to be gripped from above while it is completely enclosed by means of the tool, so that the test contact can be handled easily, quickly, reliably and safely.

The test contact comprises a contact tip and a contact body. The underside of the contact body is partially, in particular with a lower area, and/or fully installed on or in the first electronic component. The contact body may also serve as a connection point for an electrical circuit that is to be connected to a second electronic component. The assembly is preferably effected in a form-fitting manner, in particular by overmolding, and/or in a materially bonded manner, in particular by soldering. For this electrical and/or mechanical connection, the test contact has a contact tip, which is later connected to a second electronic component during use, preferably by means of a form-fitting push-fit connection.

The underside or the lower area of the contact body is the side or the area of the contact body which is disposed opposite the contact tip. Thus, the underside is “below”, the contact tip or the area on which the contact tip is indirectly disposed on the contact body thus being “above”. The lower area of the contact body does not necessarily have to be adjacent to the underside of the contact body, but can also be at a distance to it, at least the largest part of the lower area being positioned below the geometric center of gravity of the contact body.

The test contact can generally have any geometric design; preferably, the contact body has a cylindrical or cuboid shape, in particular a cubical shape, and/or has an essentially cylindrical, cuboid and/or cubic shape. Preferably, the tip has the shape of a cone or a pyramid or is essentially cone-shaped or pyramid-shaped, the base of the cone or the pyramid being disposed on the contact body or on an element disposed between the contact body and the contact tip. Particularly preferably, the contact tip and the contact body are designed in one piece together with the contact core.

The erecting direction extends from the underside and/or the lower area towards the contact tip or to the area in which the contact tip is indirectly disposed on the contact body, in other words, from the bottom to the top.

The test contact has a core made of ferromagnetic material, on which a magnetic field can exert a strong pull. It should be noted that, apart from the core, the test contact is made of an electrically conductive material and/or electrically conductive materials with a lower magnetic relative permeability. This means that the magnetic field pulls the test contact, with the exception of the core, with a weaker pull than the core itself. Preferably, the test contact, with the exception of the core, is made of one or several diamagnetic materials and/or of one or several paramagnetic materials. Particularly preferably, the test contact, with the exception of the core, is made of copper, aluminum, gold, silver or a composite and/or an alloy thereof. Where exactly the core is disposed in the test contact is arbitrary, as long as it is disposed below the center of gravity of the test contact when viewed in the erecting direction. Preferably, the core is disposed within the contact body.

By means of the test contact according to the invention, it is possible to enable the gripping of the test contact in a simple, safe and reliable manner with a single tool and in this way to enable a cost-effective and fast handling, in particular gripping, of the test contact.

The term “essentially” means that there is only a minor, in particular not significant, change, modification and/or deviation from the relevant conditions. In particular, an “essentially cylindrical, cuboid, cubic, cone-shaped or pyramid-shaped object” is, in essence, cylindrical, cuboid, cubic, cone-shaped or pyramid-shaped, whereby non-significant changes, alterations and/or deviations from the shape occur, in particular recesses or protrusions in the surface or distortions or compressions in partial areas of the basic shape or the complete basic shape.

The term “in one piece” relates to the manufacturability in one single manufacturing process, such as in particular, but by no means exclusively, in a single casting process, in particular molding the core in with the material from which the test contact, with the exception of the core, is made. In particular, it is not necessary to subsequently attach further separate components. Subsequent correction work, such as filing, is not seen as a separate manufacturing process.

The term “ferromagnetic” relates to a material having a relative permeability much larger than 1, in particular larger than 40.

The term “paramagnetic” relates to a material having a relative permeability of approximately 1, but larger than 1, in particular larger than 1 and less than 1.1.

The term “diamagnetic” relates to a material having a relative permeability of less than or equal to 1, but larger than 0.

Advantageous embodiments of the invention, which can be realized individually or in combination, are described in the dependent claims.

It is conceivable that the core is disposed in the contact body, in particular on the bottom of the contact body, opposite the contact tip. “On the bottom” means that the core forms the underside of the contact body or that the core is disposed in a lower area of the contact body, but at a distance to the underside. Preferably, the core is disposed in the lower third and at a distance to the underside. More preferably, multiple sides of the core are enclosed by the material of the rest of the contact body. Particularly preferably, the core is fully enclosed by the material of the rest of the contact body. The material of the rest of the contact body is the material from which the contact body, with the exception of the core, is made. In this manner, the contact body is reliably erected by means of the magnetic field, since the core is located well below the center of gravity of the test contact. Even more preferably, the contact area is disposed within the contact body above the core. The contact area is the area which, in an installed state of the test contact in a first component, is connected to the first component in such a manner that an electric current can flow in the area from or to the first component via the test contact to or from the contact tip. With this arrangement, an electric current conducted through the test contact from the first component to the second component is not conducted through the core. Therefore, the electrotechnical properties of the core material, in particular the electrical conductivity, can be disregarded for the design of the test contact.

The term “at a distance to the underside” relates to an arrangement in which at least a layer of the material of the rest of the contact body is disposed below the core.

In another embodiment of the invention, it is conceivable that the contact body comprises an installation surface and the core is formed planar and parallel to the installation surface. The installation surface is disposed at the bottom of the contact body. Due to the planar and parallel design of the core, the pull of the magnetic field creates a leverage effect which places the test contact on the installation surface. The installation surface ensures that the test contact stands securely and firmly on it when the magnetic field is activated. If the contact body has a cylindrical or cuboid shape (as described elsewhere), the installation surface preferably corresponds to the lower end face of the cylinder or to an end face of the cuboid. The installation surface is preferably planar.

Furthermore, it is conceivable that the core is made of iron, nickel or cobalt, has an iron, nickel- and/or cobalt content or is made of a ferromagnetic alloy, in particular a ferromagnetic iron, nickel and/or cobalt alloy. These materials are ferromagnetic materials whose magnetic permeability coefficient is sufficiently high to ensure that the test contact is erected by the impact of the pull of a magnet.

In another embodiment of the invention, it is conceivable that the test contact comprises an arm, the contact body being disposed on one end of said arm and the contact tip being disposed on the other end of said arm. Preferably, the contact tip points away from the arm at an angle of 90°. Designing contact tips which laterally project from the component and which project upwards and downwards by 90° is common and widespread, in particular for chips. An example of such an embodiment is the dual in-line package. With this design, it is also important to note that the center of gravity is usually located outside the contact body. Therefore, a test contact designed in this way falls over under the impact of gravity. If the test contact has a ferromagnetic core according to the invention, this test contact can also be set up and processed quickly and easily. The design with an arm is one possible, but by no means exclusive, indirect arrangement of the contact tip on the contact body, as described elsewhere.

The definitions and/or the explanations of the terms mentioned above are assumed to apply to all aspects described in the following description, unless otherwise indicated.

The invention also proposes a table device for handling a test contact (described above), the table device comprising a plate. The table device is characterized in that a magnetic field unit comprising at least one magnet is disposed on the plate such that the magnetic field of the magnet emerges essentially perpendicular from the plate.

As described above, it has been recognized as advantageous that the test contact is erected and set up for handling in this way, as subsequent further handling of the test contact is possible in a simple and reliable manner in terms of the process. To this end, one or several test contact(s) are disposed on the plate. The magnetic field unit having the at least one magnet, which is disposed such that the magnetic field of the magnet emerges essentially perpendicular from the plate, pulls the core of the test contact by means of the generated magnetic field, whereby a pull acts on the core. Since, according to the invention, the core is disposed below the center of gravity of the test contact, the test contact is erected. This is done in the same way as with a roly-poly toy, except that a magnetic force acts on the test contact instead of the gravitational force. Once the test contact has been put in the upright position, the test contact can subsequently be handled in a quick, easy and uncomplicated manner. The plate can have any design. However, it should be horizontal and planar. It is conceivable that the magnetic field unit preferably comprises at least 2, 3, 4, 5, 6, 7, 8, 9, 10, 11, 12, 13, 14, 15, 16, 17, 18, 19, 20, 25, 30, 35, 40, 45, 50, 60, 70, 80, 90 or 100 identically or differently designed magnets. More preferably, the magnetic field unit comprises a control unit for activating and deactivating the magnet or the magnets. In particular, the magnet is an electromagnet and the control unit closes a switch in an electrical conductor to or from the electromagnet to activate the electromagnet and opens the switch to deactivate the electromagnet.

In the present invention, “emerging essentially perpendicular from the plate” in particular means that the field directions of the magnetic field in the area of the plate in which the test contact is to be placed deviate by no more than 15° from the perpendicular of the plate.

In another embodiment of the invention, it is conceivable that the magnet is disposed below, within, next to and/or above the plate. This is advantageous in that the force acting on the test contact acts maximally in the intended direction. This ensures the desired effect, i.e., the erecting of the test contact. The shape, alignment and/or design of the magnet must be matched to the respective arrangement. It is obvious that a magnet disposed above the plate must be disposed at a distance to the plate which at least allows a handling. In particular, it is conceivable that a bar magnet is disposed below, above, next to and/or in the center within the plate, one pole being disposed at the top and the other pole being disposed at the bottom. Thus, the magnetic field emerges essentially perpendicular from the plate, whereby, depending on the arrangement, a different area of the magnetic field emerges from the plate. In particular with a horseshoe magnet, it is conceivable that one leg is disposed above and the other leg is disposed below and the transverse beam connecting the legs is disposed next to the plate. The legs are oriented parallel to the plate. In this manner, the homogenous part of the magnetic field of the horseshoe magnet emerges perpendicular from the plate.

Furthermore, it is conceivable that the magnet is an electromagnet or a permanent magnet. An electromagnet is advantageous in that it can be activated and/or deactivated. Thus, it is possible to only activate the magnet once the test contact has been placed on the plate, such that the test contact can be positioned easily in the correct position. Furthermore, the electromagnet can be deactivated after or during the handling, such that the magnetic forces no longer act on the test contact as soon as it is handled. For example, the test contact is gripped and lifted up by a tool. If the electromagnet is deactivated in the moment of the lifting up, a smaller force acts on the test contact and/or a smaller force is required for gripping the test contact. This prevents damage, in particular a bending, of the test contact during handling. A permanent magnet or a permanently activated electromagnet is advantageous in that the magnetic force permanently acts on a test contact placed on the plate, such that the test contact is held more safely on the plate and is less likely to be knocked off the plate by the influence of external forces.

In one embodiment of the invention, it is conceivable that the table device comprises at least one insert, the insert being disposed on or in the upper side of the plate. The insert is the area in which the test contact can be placed. It is conceivable that the insert and the test contact are placed and/or put onto the plate together. The insert serves as a vessel for transporting the test contact. To this end, the insert is preferably designed with an edge and/or a lid. Furthermore, the insert can be optimized for the placement the test contact, while the plate is optimized for the transmission of the magnetic field. For example, the insert can be cleaned particularly easily and/or can be antistatic. Preferably, the insert is made of glass. Particularly preferably, the table device comprises at least 3, 4, 5, 6, 7, 8, 9, 10, 11, 12, 13, 14, 15, 16, 17, 18, 19, 20, 25, 30, 35, 40, 45, 50, 60, 70, 80, 90 or 100 inserts. To place the insert at the correct position in the plate, it is preferred if the plate has a corresponding recess, such that the insert is disposed in the upper side of the plate. Particularly preferably, the table device comprises at least two inserts, the magnetic field unit comprising at least a number of electromagnets corresponding to the number of the inserts, each insert being assigned at least one of the electromagnets and the assigned electromagnet being disposed such that the magnetic field of the assigned electromagnet emerges essentially perpendicular from the assigned insert. In this manner, two or more test contacts according to the invention can be placed on the table device and can be individually prepared for the handling. In particular, this enables continuous and/or simultaneous handling or preparation for handling the test contacts, whereby the different methods are located at different points or in different steps. This speeds up the handling.

The term “on the upper side of the plate” means that the insert rests on top of the plate and is form-fittingly connected and/or materially bonded thereto, if applicable.

The term “in the upper side of the plate” means that the insert is partly or fully sunk within a corresponding recess.

In another embodiment of the invention, it is conceivable that the plate is made of a paramagnetic material. If the relative magnetic permeability of the material from which the plate is made is too high, as is the case with a ferromagnetic material, for example, the magnetic field is bundled by the plate in a shielding manner and is unable to act on the core of the test contact resting on the plate. If it is a diamagnetic material, the magnetic field is displaced from the plate and cannot or can only weakly impact the core of the test contact. Paramagnetic materials have a sufficiently low, but not too low, relative magnetic permeability. They also minimize losses when using electromagnets that are activated or deactivated during handling, as only low hysteresis losses occur in the plate.

The invention also proposes a method for handling a test contact (described elsewhere) by means of a table device (described elsewhere), the method comprising the following steps:
a. Placing the test contact on the plate of the table device;
b. Erecting the test contact by activating the magnet.

Erecting the test contact allows it to be handled easily by means of simpler and fewer tools or by hand. This is due to the fact that the test contact has a predictable spatial orientation in which the tip of the test contact is raised. If necessary, the tool only needs to be rotated around an axis to enable a handling. The erecting of the test contact is effected by the ferromagnetic core on which the magnetic field of the activated magnet acts (as described elsewhere), said ferromagnetic core being disposed below the center of gravity. It is conceivable that step a. is carried out multiple times. This means that several test contacts, in particular at least two test contacts, are placed on the plate of the table device. Furthermore, it is conceivable that several test contacts, in particular at least two test contacts, are erected by activating the magnet in step b. It is also conceivable that several methods and/or method steps are carried out simultaneously or with a time delay.

In another embodiment, the method comprises a step c. after step b., i.e., gripping the test contact by means of a handling unit. Particularly preferably, the gripper can be rotated around an axis, in particular around the Z axis. This allows the test contact to be gripped so as to be correctly aligned. It is conceivable to move the gripper using a Cartesian axis system with a Z axis. For this purpose, a slide with a gripper is moved in the XY plane by means of a linkage, whereby the gripper can be moved on the slide and/or together with the slide in the Z axis, which is perpendicular to the XY plane. The XY plane is the plane that is disposed parallel to the plate. Alternatively, it is conceivable that the gripper is disposed on a robot arm. After the robot arm or the Cartesian axis system with the Z axis has gripped the test contact, it can lift said test contact and position it at any location. For example, the robot arm or the Cartesian axis system with the Z axis can place the test contact at a previously determined position of a first electronic component, insert it into the component and/or fix it in place there.

Additionally, it is conceivable that the magnet is deactivated after it has been gripped and the handling unit moves together with the gripper which is disposed thereon. This means that the robot arm or the Cartesian axis system with the Z axis transports the test contact to a different position. By deactivating the magnet, the magnetic forces no longer act on the test contact such that the gripper can be equipped with a weaker grip force. This reduces the overall forces acting on the test contact and protects the test contact.

Furthermore, the invention proposes a test contact holding device comprising a test contact holder for handling a test contact (as described elsewhere), the test contact holder comprising a magnetic field unit. The test contact holding device is characterized in that the test contact holder comprises an in particular vertical contact surface, the magnetic field unit comprising at least one magnet, the magnet being disposed such that the magnetic field of the magnet is essentially parallel to the contact surface.

As has been described previously, it has been discovered that it is advantageous if the test contact is erected and set up for handling in this way, as subsequent further handling of the test contact is possible in a simple and reliable manner in terms of the process. To achieve an erection, the test contact holder is moved towards at least one test contact in such a way that the test contact is within the operating range of the magnetic field unit. This means that the magnetic field of the magnet of the magnetic field unit can act on the one test contact or on several test contacts in such a way that the one test contact or the several test contacts are erected under the influence of the magnetic field. It is particularly advantageous if the test contact is erected at an angle such that it is parallel to the contact surface of the test contact holder on which it is to be held. For this purpose, the field lines of the magnetic field must be essentially parallel to the contact surface so that the force acting on the test contact is also essentially parallel to the contact surface. The magnet attracts the core of the test contact or the test contacts by means of the magnetic field caused, whereby a pull acts on the core. Since, according to the invention, the core is disposed below the center of gravity of the test contact, the test contact is erected. This is done in the same way as with a roly-poly toy, except that a magnetic force acts on the test contact instead of the gravitational force. This effect or the essentially parallel course of the magnetic field parallel to the contact surface is achieved by suitably arranging and aligning the magnetic field unit. Once the test contact has been brought into the upright position, a subsequent handling of the test contact is possible in a quick, simple and uncomplicated manner, in particular by placing and holding the test contact on the contact surface. Receiving the test contact is preferably effected by erecting it by means of the magnetic field and fixing it to the receiving surface. It is conceivable that the magnetic field unit preferably comprises at least 2, 3, 4, 5, 6, 7, 8, 9, 10, 11, 12, 13, 14, 15, 16, 17, 18, 19, 20, 25, 30, 35, 40, 45, 50, 60, 70, 80, 90 or 100 identically or differently designed magnets. More preferably, the magnetic field unit comprises a control unit for activating and deactivating the magnet or the magnets. In particular, the magnet is an electromagnet and the control unit closes a switch in an electrical conductor to or from the electromagnet to activate the electromagnet and opens the switch to deactivate the electromagnet. More preferably, the test contact holder can be moved spatially in order to be able to pick up the test contact on the essentially vertical contact surface and transport it to another location. It is preferably possible for the test contact holder to rotate the test contact about one, two or three spatial axes. Particularly preferably, the test contact holder comprises a track system and/or a linkage system and/or a robot arm in order to achieve the required movability. Preferably, it is conceivable to move the test contact holder by means of a Cartesian axis system with a Z axis. For this purpose, a slide with the test contact holder is moved in the XY plane by means of a linkage, whereby the test contact holder can be moved on the slide and/or together with the slide in the Z axis, which is perpendicular to the XY plane. The XY plane is the plane that is disposed parallel to the plate. Alternatively, it is conceivable that the test contact holder is disposed on a robot arm. After the robot arm or the Cartesian axis system with the Z axis has gripped the test contact, it can lift said test contact and position it at any location. For example, the robot arm or the Cartesian axis system with the Z axis can place the test contact at a previously determined position of a first electronic component, insert it into the component and/or fix it in place there.

Particularly preferably, in particular when receiving the test contacts, the contact surface is disposed vertically to the supporting surface on which the test contacts rest before being received by the test contact holding device, or said contact surface is disposed at an acute angle, particularly preferably at an angle not exceeding 45°, 40°, 35°, 30°, 25°, 20°, 15°, 10° and/or 5°.

In the present invention, the term “essentially parallel” relates to a parallel arrangement or an arrangement forming an acute angle, in particular an angle not exceeding 15°.

In another embodiment of the invention, it is conceivable that the magnet is disposed above and/or behind the contact surface, forms a part of the contact surface or forms the contact surface. This is advantageous in that the force acting on the test contact acts maximally in the intended direction. This ensures the desired effect, i.e., the erecting of the test contact parallel to the contact surface. The shape, alignment and/or design of the magnet must be matched to the respective arrangement. It is obvious that a magnet disposed within and/or behind the contact surface must be aligned such that the field direction of the magnetic field is essentially parallel to the contact surface in the manner according to the invention. If the magnet itself forms a part of the contact surface or a surface of the magnet forms the contact surface, a correct alignment must also be ensured during manufacture and/or arrangement in order to ensure that the magnetic field is essentially parallel to the contact surface in accordance with the invention.

Moreover, it is conceivable that the magnet is an electromagnet or a permanent magnet. An electromagnet is advantageous in that it can be activated and/or deactivated. Thus, it is possible to only activate the magnet once the test contact has been placed in the operating range of the test contact holder, such that the test contact can be positioned easily in the correct position. Furthermore, the electromagnet can be deactivated after or during the handling, such that the magnetic forces no longer act on the test contact. For example, if the magnetic field holds the test contact on the essentially vertical contact surface, the test contact is released by deactivating the magnetic field. This allows the test contact holder of the test contact holding device to quickly and easily deposit the test contact at a designated location. This prevents damage, in particular a bending, of the test contact during handling. A permanent magnet or a permanently activated electromagnet is advantageous in that the magnetic force acts as early as when the test contact holder approaches the test contact, such that the test contact is already erected and can thus be gripped more quickly.

It is also conceivable that the test contact holding device comprises a gripper. The gripper can hold the test contact on the contact surface in addition or as an alternative to the magnetic field. The gripper is preferably a pincer gripper, a two-, three- and/or four-finger gripper.

In a preferred embodiment of the invention, it is conceivable that the test contact holding device comprises at least one transmission channel for transmitting thermal energy and/or for transferring negative pressure, a channel mouth of the transmission channel being disposed in the area of the contact surface. By means of the negative pressure, the test contact is held on the contact surface in a quick, easy and protected manner. The transfer of heat heats the test contact in a targeted manner, such that the test contact can be attached to the first electronic component by means of soldering. Particularly preferably, the heat is introduced into the test contact by means of laser energy.

In a further embodiment, the test contact holder comprises two parallel receiving flanks forming a receiving gap, the transmission channel being disposed above the receiving gap and ending in the receiving gap, and at least one inner side of the receiving flanks which forms the receiving gap forming the contact surface. After it has been received, the test contact is disposed in the receiving gap and is held by the negative pressure in the receiving gap. It is also conceivable that each of the two inner sides forms one contact surface. After it has been received, the test contact abuts against either one of the contact surfaces or against both contact surfaces simultaneously.

In another preferred embodiment, the test contact holding device comprises a positioning unit having at least two positioning surfaces, the first of the positioning surfaces comprising the contact surface. The test contact, in particular an absorption area of the test contact, is fixed in place on the positioning surfaces of the positioning unit. An exact positioning of the test contact on the test contact holding device is ensured by the two positioning surfaces. Particularly preferably, the positioning surfaces are disposed at a right angle with respect to each other.

In another embodiment of the invention, it is conceivable that the contact surface is formed by the lateral surface of a wedge. Preferably, the wedge is made of a paramagnetic material. If the relative magnetic permeability of the material from which the wedge is made is too high, as is the case with a ferromagnetic material, for example, the magnetic field is bundled by the wedge in a shielding manner and is unable to act on the core of the test contact located in the intended operating range of the test contact holder. If it is a diamagnetic material, the magnetic field is displaced from the wedge and cannot or can only weakly impact the core of the test contact. Paramagnetic materials have a sufficiently low, but not too low, relative magnetic permeability. They also minimize losses when using electromagnets that are activated or deactivated during handling, as only low hysteresis losses occur in the wedge.

The invention also proposes a method for handling a test contact (described elsewhere) by means of a test contact holding device (described elsewhere), the method comprising the following steps:
a. Placing the test contact on a position accessible by the test contact holder;
b. Moving the test contact holder towards the test contact;
c. Erecting the test contact by activating the magnet;
d. Receiving the test contact by means of the test contact holder.

Erecting the test contact allows handling it by means of the test contact holding device or by hand in a simple manner. This is due to the fact that the test contact has a predictable spatial orientation in which the tip of the test contact is raised. If necessary, the test contact holder only needs to be moved towards the test contact and rotated around an axis to enable a handling. The erecting of the test contact is effected by the ferromagnetic core on which the magnetic field of the activated magnet acts (as described elsewhere), said ferromagnetic core being disposed below the center of gravity. It is conceivable that step a. is carried out multiple times. This means that several test contacts, in particular at least two test contacts, are placed on a position accessible by the test contact holder. It is also conceivable that the test contact holder is randomly disposed in such a manner that it is not necessary to move the test contact holder towards one of the test contacts. Furthermore, it is conceivable that several test contacts, in particular at least two test contacts, are erected by activating the magnet in step c. It is also conceivable that several methods and/or method steps are carried out simultaneously or with a time delay, in particular by means of several test contact holders. After the test contact has been received by the test contact holder, the test contact holder can preferably place the test contact at a previously determined position of a first electronic component, insert it into the component and/or fix it in place there.

Additionally, it is conceivable that the receiving in step d. is effected magnetically and/or mechanically, in particular by gripping. The magnetic field of the activated magnet holds the test contact on the contact surface and/or the test contact is received on the contact surface in a form-fitting and/or frictionally engaged manner.

In particular, it is conceivable to combine individual, several and/or all steps of the previously described method for handling a test contact by means of a table device with individual, several and/or all steps of the previously described method for handling a test contact by means of a test contact holding device. The steps can be carried out successively, in turs and/or simultaneously.

Further details, features and advantages of the invention are apparent from the following description of preferred illustrative examples in connection with the dependent claims. The respective features can be realized individually or in combination with each other. The invention is not limited to the illustrative examples. The illustrative examples are schematically illustrated in the figures. Identical reference signs in the individual figures designate similar elements, elements of similar functions or elements corresponding in terms of functionality.

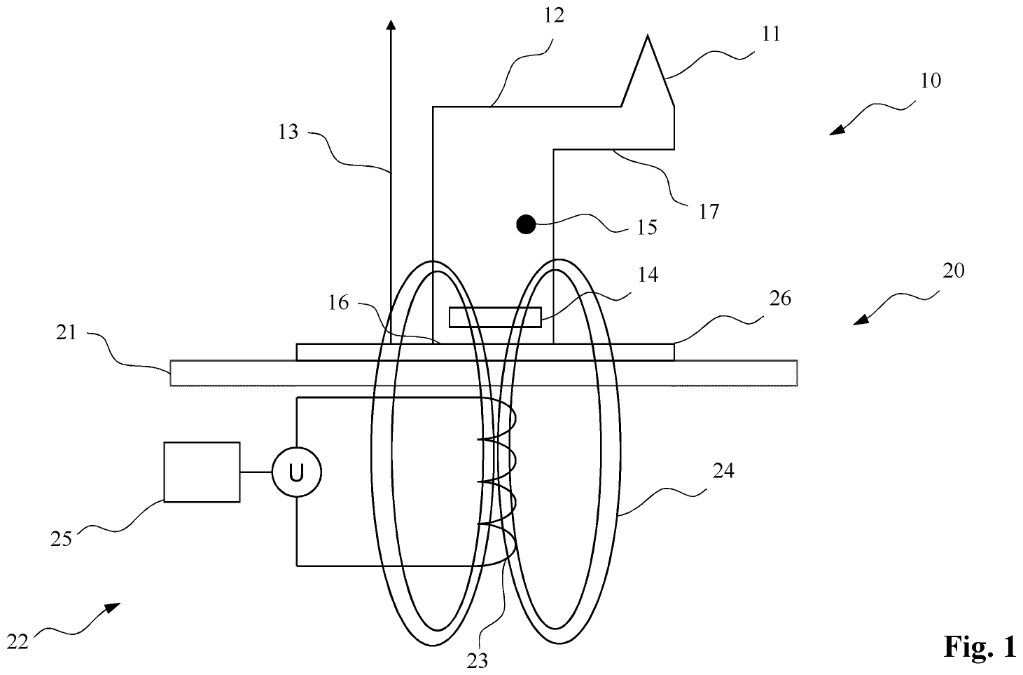

FIG. 1 shows a test contact according to the invention which is disposed on a first embodiment of a table device according to the invention;

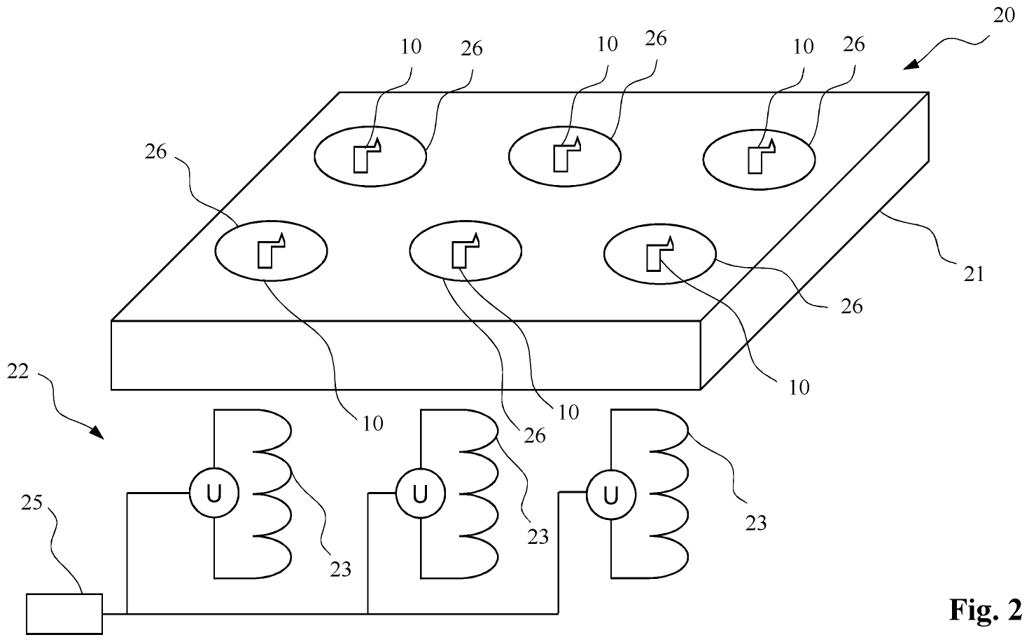

FIG. 2 shows six test contacts according to the invention which are disposed on a second embodiment of a table device according to the invention;

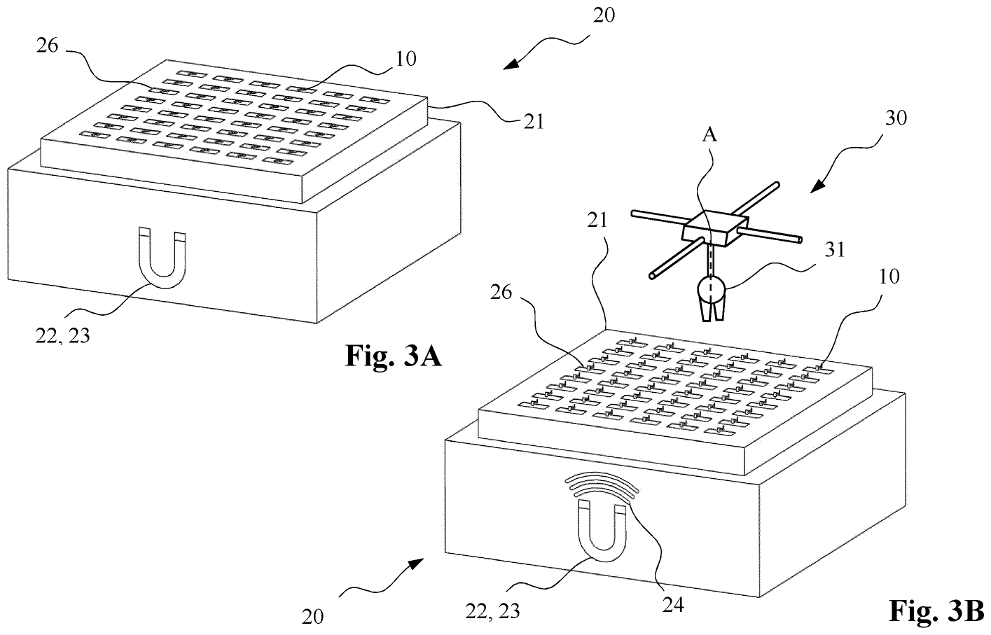

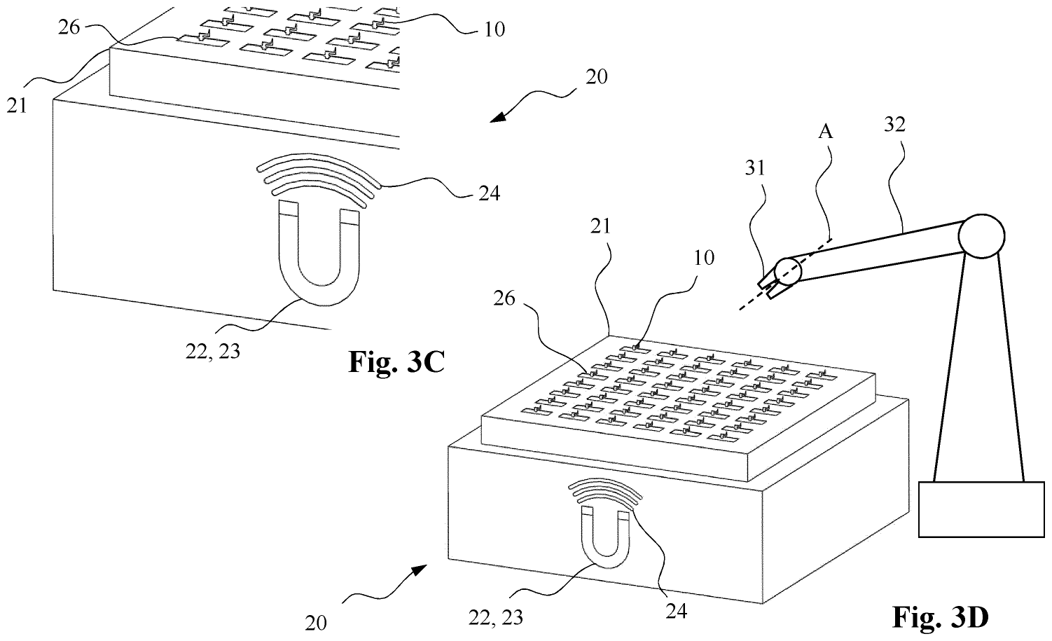

FIG. 3A to FIG. 3D show a plurality of test contacts according to the invention which are disposed on a third embodiment of a table device according to the invention, the handling method according to the invention being realized by means of the table device; and

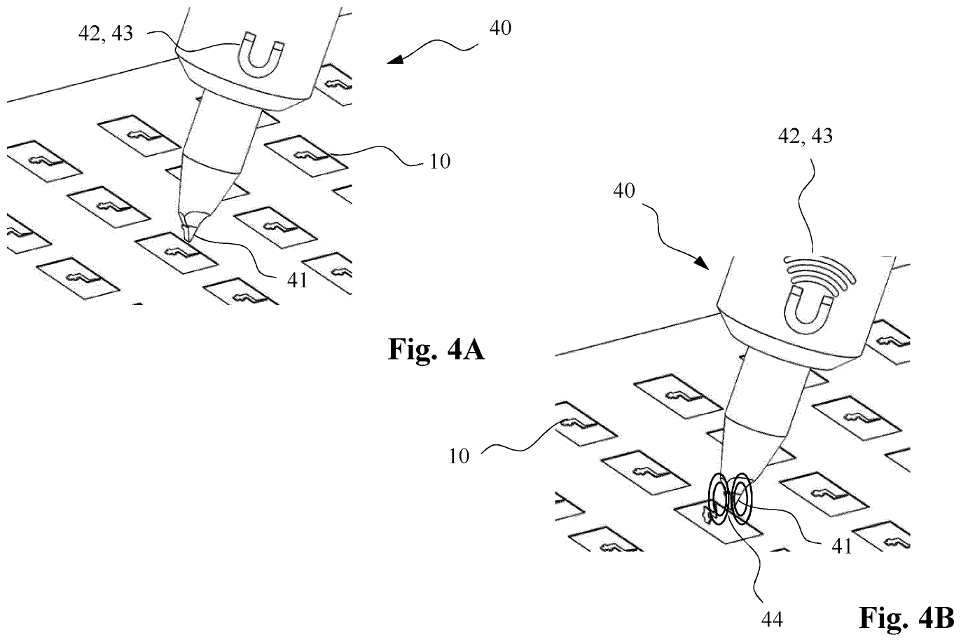

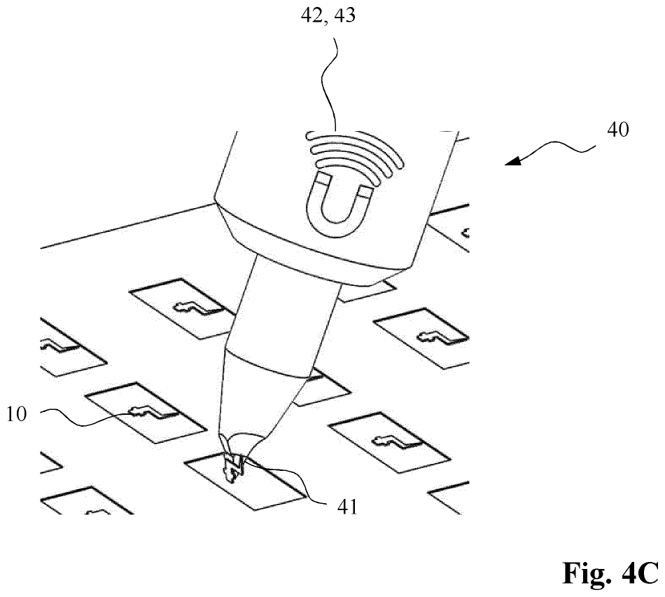

FIG. 4A to FIG. 4C show a plurality of test contacts according to the invention which are disposed in the operating range of a test contact holder of a first embodiment of a test contact holding device according to the invention, the handling method according to the invention being realized by means of the test contact holding device.

FIG. 1 shows a test contact 10 according to the invention which is disposed on a first embodiment of a table device 20 according to the invention. Test contact 10 comprises a contact tip 11 and a contact body 12. Via contact body 12, test contact 10 is connected to a first component (not shown), such that a second component (not shown) can be mounted on contact tip 11 later. A vertical arm 17 is disposed on the upper side of contact body 12, contact tip 11 being formed on the other end of said arm 17. Test contact 10 has a center of gravity 15. Furthermore, test contact 10 has an erecting direction 13, the erecting direction extending from the bottom to the top. Contact tip 11 is parallel to erecting direction 13. Furthermore, test contact 10 comprises a core 14 which is made of a ferromagnetic material and which is disposed below center of gravity 15. In the embodiment shown in FIG. 1, core 14 has an elongated design and is disposed parallel to an installation surface 16 on which test contact 10 stands. Test contact 10 is disposed on an insert 26 of table device 20. Insert 26 is placed on a plate 21 of table device 20. A magnetic field unit 22 comprising a magnet 23 is located below plate 21. This embodiment is an electromagnetic magnet which can be activated and/or deactivated by means of a control unit 25. In FIG. 1, magnet 23 is activated and thus exerts a magnetic field 24 which emerges essentially perpendicular through plate 21 and insert 26.

Magnetic field 24 generates a force acting on core 14 and thus erects test contact 10 on installation surface 16.

FIG. 2 shows six test contacts 10 according to the invention which are disposed on a second embodiment of a table device 20 according to the invention. In principle, the second embodiment of table device 20 corresponds to the first embodiment of table device 20 according to the invention shown in FIG. 1. However, it is different to the embodiment shown in FIG. 1 in that it comprises six inserts 26 on which six test contacts 10 can be disposed. Inserts 26 are evenly distributed on a plate 21. A magnetic field unit 22 is disposed below plate 21, said magnetic field unit 22 comprising six magnets 23, which can be activated and/or deactivated by means of a control unit 25, although only the front three magnets 23 are shown in FIG. 2. Each insert 26 is associated with one magnet 23. Individual magnets 23 can be activated separately, such that a parallel processing of test contacts 10 is possible.

FIG. 3A shows a third embodiment of a table device 20 according to the invention, table device 20 comprising a plurality of inserts 26. One test contact 10 is disposed on each insert 26. A magnetic field unit 22 is disposed below a plate 21, said magnetic field unit 22 comprising a controllable magnet 23 which is deactivated in FIG. 3A. Step a., i.e., placing test contact 10 on plate 21 of table device 20, has already been performed multiple times in FIG. 3A.

FIG. 3B shows table device 20 from FIG. 3A, magnet 23 being activated, such that a magnetic field 24 is emitted from magnet 23. Magnetic field 24 erects test contacts 10, 20 on inserts 26. This means that step b., i.e., erecting test contacts 10 by activating magnet 23, has been performed. Because of their upright position, test contacts 10 can be gripped in a simple manner by a gripper 31 which is disposed on a Cartesian axis system 30. Cartesian axis system 30 comprises a slide on which gripper 31 is disposed, the slide being moved by means of a linkage. Gripper 31 can be rotated about the Z axis and can be moved along the Z axis.

FIG. 3C shows an enlarged section of table device 20, magnetic field unit 22 being activated. Thus, magnet 23 emits the magnetic field 24 such that test contacts 10 are erected on inserts 26 in plate 21.

FIG. 3D shows an alternative embodiment, gripper 31 being disposed on a multiaxial robot arm 32. Gripper 31 can also be rotated about an axis A.

FIG. 4A shows a plurality of test contacts 10 according to the invention which are disposed in the operating range of a test contact holder 40 of a first embodiment of a test contact holding device according to the invention. Test contact holder 40 comprises a contact surface 41 formed by the lateral surface of a wedge. Furthermore, test contact holder 40 comprises a magnetic field unit 42 having a magnet 43. In this case, magnet 43 is an electromagnet which can be activated and deactivated. Test contact holder 40 has been moved towards one of test contacts 10, such that said test contact is within the operating range of magnet 43.

In FIG. 4B, magnet 43 of magnetic field unit 42 has been activated such that a magnetic field 44 is generated. Test contact 10, which is located in striking distance of contact surface 41, has erected itself as a consequence of magnetic field 44.

In FIG. 4C, test contact 10 has been picked up and is held on contact surface 41 by magnetic field 44 (not shown in FIG. 4A) of magnet 43. Subsequently, test contact holder 40 can be moved together with test contact 41.

1. A test contact (10) comprising a contact tip (11) and a contact body (12), the test contact (10) having an erecting direction (13), wherein the test contact (10) comprises a core (14) made of a ferromagnetic material, the core being disposed below a center of gravity (15) of the test contact (10) in the erecting direction (13).

2. The test contact (10) according to claim 1, wherein the core (14) is disposed in the contact body (12) opposite the contact tip (11).

3. The test contact (10) according to claim 1, wherein the contact body (12) comprises an installation surface (16) and the core (14) is formed planar and parallel to the installation surface (16).

4. The test contact (10) according to claim 1, wherein the core (14) is made of iron, nickel or cobalt, has an iron, nickel or cobalt content or is made of a ferromagnetic alloy.

5. The test contact (10) according to claim 1, wherein the test contact (10) comprises an arm (17), the contact body (12) being disposed on one end of said arm (17) and the contact tip (11) being disposed on the other end of said arm (17).

6. A table device (20) for handling a test contact (10) according to claim 1, the table device (20) comprising a plate (21), wherein a magnetic field unit (22) comprising at least one magnet (23) is disposed on the plate (21) such that the magnetic field (24) of the magnet (23) emerges essentially perpendicular from the plate (21).

7. The table device (20) according to claim 6, wherein the magnet (23) is disposed below, within, next to or above the plate (21).

8. The table device (20) according to claim 6, wherein the magnet (23) is an electromagnet or a permanent magnet.

9. The table device (20) according to claim 6, wherein the table device (20) comprises at least one insert (26), the insert (26) being disposed on or in the upper side of the plate (21).

10. The table device (20) according to claim 9, wherein the insert (26) is made of glass.

11. The table device (20) according to claim 9, wherein the device comprises at least two inserts (26) and that the magnetic field unit (22) comprises at least a number of electromagnets corresponding to the number of the inserts (26), each insert (26) being assigned at least one of the electromagnets, the assigned electromagnet being disposed such that the magnetic field (24) of the assigned electromagnet emerges essentially perpendicular from the assigned insert (26).

12. The table device (20) according to claim 6, wherein the plate (21) is made of a paramagnetic material.

13. A method for handling a test contact (10) according to claim 1 by means of a table device (20), comprising a plate (21), wherein a magnetic field unit (22) comprising at least one magnet (23) is disposed on the plate (21) such that the magnetic field (24) of the magnet (23) emerges essentially perpendicular from the plate (21), the method comprising the following steps:
a. Placing the test contact (10) on the plate (21) of the table device (20);
b. Erecting the test contact (10) by activating the magnet (23).

14. The method according to claim 13, the method comprising the following step after step b.:
c. Gripping the test contact (10) by means of a handling unit.

15. The method according to claim 14, the method comprising the following step after step c.:
d. Deactivating the magnet (23) and moving the handling unit.

16. A test contact holding device comprising a test contact holder (40) for handling a test contact (10) according to claim 1, the test contact holder (40) comprising a magnetic field unit (42), wherein the test contact holder (40) comprises a vertical contact surface (41), the magnetic field unit (42) comprising at least one magnet (43), the magnet (43) being disposed such that the magnetic field (44) of the magnet (43) is essentially parallel to the contact surface (41).

17. The test contact holding device according to claim 16, wherein the magnet (43) is disposed above or behind the contact surface (41), forms a part of the contact surface (41) or forms the contact surface (41).

18. The test contact holding device according to claim 16, wherein the magnet (43) is an electromagnet or a permanent magnet.

19. The test contact holding device according to claim 16, wherein the test contact holder (40) comprises a gripper.

20. The test contact holding device according to claim 16, wherein the test contact holding device comprises at least one transmission channel for transmitting thermal energy or for transferring negative pressure, a channel mouth of the transmission channel being disposed in the area of the contact surface (41).

21. The test contact holding device according to claim 16, wherein the essentially vertical contact surface (41) is formed by the lateral surface of a wedge.

22. A method for handling a test contact (10) comprising a contact tip (11) and a contact body (12), the test contact (10) having an erecting direction (13), wherein the test contact (10) comprises a core (14) made of a ferromagnetic material, the core being disposed below a center of gravity (15) of the test contact (10) in the erecting direction (13), by means of a test contact holding device according to claim 16, the method comprising the following steps:
a. Placing the test contact (10) on a position accessible by the test contact holder (40);
b. Moving the test contact holder (40) towards the test contact (10);
c. Erecting the test contact (10) by activating the magnet (43);
d. Receiving the test contact (10) by means of the test contact holder (40).

23. The method according to claim 22, the receiving in step d. being effected magnetically or mechanically.
